(19) United States
(12) Patent Application Publication
(10) Pub. No.: US 2026/0291184 A1
(43) Pub. Date: Sep. 24, 2026

(54) EDGE-EMITTING LASER DIODE, RELATED APPARATUSES, DATA STORAGE DEVICES, SYSTEMS, AND METHODS

(71) Applicant: Seagate Technology LLC, Fremont, CA (US)

(72) Inventors: Vivek Krishnamurthy, Eden Prairie, MN (US); Michael Allen Seigler, Eden Prairie, MN (US); Lars Halvar Ahlen, Minneapolis, MN (US); Reyad Mehfuz, Derry (GB); Michael Gerald Boyle, Derry (GB)

(21) Appl. No.: 19/572,376

(22) Filed: Mar. 19, 2026

Related U.S. Application Data
(60) Provisional application No. 63/775,208, filed on Mar. 20, 2025.

(51) Int. Cl. H01S 5/40; G11B 5/60; H01S 5/02; H01S 5/028; H01S 5/042; H01S 5/22; G11B 5/00

(52) U.S. Cl. CPC H01S 5/4031; G11B 5/6088; H01S 5/0201; H01S 5/0282; H01S 5/0421; H01S 5/22; G11B 2005/0021

(57) ABSTRACT

An edge-emitting laser diode includes a body having a base and a ridge waveguide with an active region disposed between a first etched facet and a second etched facet. The ridge waveguide is configured to confine and direct light toward the second etched facet. At least the first and second etched facets are encapsulated in a dielectric encapsulation material. A p-metal electrical contact and an n-metal electrical contact extend from the body through the dielectric encapsulation material for electrical connection. The edge-emitting laser diode is configured to be mounted to an external surface of a component of an apparatus to communicate light from the second etched facet to a waveguide in the apparatus. Also disclosed are a wafer, a bar, an apparatus including a slider having a waveguide and a near-field transducer, and methods of fabricating and assembling the edge-emitting laser diode.

### CROSS-REFERENCE TO RELATED APPLICATION

This nonprovisional patent application claims the benefit of U.S. Provisional Patent Application Serial Number 63/775,208, filed on Mar. 20, 2025, wherein said provisional patent application is incorporated herein by reference in its entirety.

### SUMMARY

The present disclosure includes embodiments of an edge-emitting laser diode that includes a body. The body includes a base and a ridge waveguide disposed adjacent to the base. The ridge waveguide includes an active region. The edge-emitting laser diode further includes a first etched facet and a second etched facet. The active region is disposed between the first etched facet and the second etched facet. The ridge waveguide is configured to confine light generated in the active region and direct light toward the second etched facet. The edge-emitting laser diode further includes a p-metal electrical contact and an n-metal electrical contact. At least the first etched facet and the second etched facet are encapsulated in a dielectric encapsulation material. The p-metal electrical contact and the n-metal electrical contact extend from the body through the dielectric encapsulation material so that each of the p-metal electrical contact and the n-metal electrical contact are exposed for electrical connection. The edge-emitting laser diode is configured to be mounted to an external surface of a component of an apparatus to communicate light from the second etched facet to a waveguide in the apparatus.

The present disclosure also includes embodiments of a wafer that includes a substrate and a plurality of edge-emitting laser diode intermediates. Each edge-emitting laser diode intermediate includes a body. The body includes a base and a ridge waveguide disposed adjacent to the base. The ridge waveguide includes an active region. Each edge-emitting laser diode intermediate further includes a first etched facet and a second etched facet. The active region is disposed between the first etched facet and the second etched facet. The ridge waveguide is configured to confine light generated in the active region and direct light toward the second etched facet. At least the first etched facet and the second etched facet are encapsulated in a dielectric encapsulation material.

The present disclosure also includes embodiments of a bar that includes a substrate and a single row of a plurality of edge-emitting laser diode intermediates. Each edge-emitting laser diode intermediate includes a body. The body includes a base and a ridge waveguide disposed adjacent to the base. The ridge waveguide includes an active region. Each edge-emitting laser diode intermediate further includes a first etched facet and a second etched facet. The active region is disposed between the first etched facet and the second etched facet. The ridge waveguide is configured to confine light generated in the active region and direct light toward the second etched facet. At least the first etched facet and the second etched facet are encapsulated in a dielectric encapsulation material.

The present disclosure also includes embodiments of a method that includes etching a plurality of edge-emitting laser diode intermediates disposed on a wafer to form a first etched facet and a second etched facet in each of the plurality of edge-emitting laser diode intermediates. An active region is disposed between the first etched facet and the second etched facet. Each edge-emitting laser diode intermediate includes a ridge waveguide configured to confine light generated in the active region and direct light toward the second etched facet. The method further includes encapsulating at least the first etched facet and the second etched facet in a dielectric encapsulation material.

### BRIEF DESCRIPTION OF THE DRAWINGS

Various examples of the present disclosure will be discussed with reference to the appended drawings. These drawings depict only illustrative examples of the disclosure and are not to be considered limiting of its scope.

FIG. 1 is a perspective view of a slider with a laser diode and submount according to the prior art;

FIG. 2A is a top view of a wafer showing a plurality of edge-emitting laser diode intermediates during manufacture of edge-emitting laser diodes according to the present disclosure;

FIG. 2B is an enlarged top view of an edge-emitting laser diode intermediate shown in FIG. 2A;

FIG. 3A is an enlarged top view of an edge-emitting laser diode intermediate shown in FIG. 2A after encapsulation;

FIG. 3B is a cross-sectional, elevation view along the width of the edge-emitting laser diode intermediate shown in FIG. 3A;

FIG. 3C is a cross-sectional, elevation view along the length of the edge-emitting laser diode intermediate shown in FIG. 3A;

FIG. 4A is a top view of a wafer showing a row of edge-emitting laser diode intermediates prior to being separated from a wafer into a bar during manufacture of edge-emitting laser diodes according to the present disclosure;

FIG. 4B is a top view of a bar of edge-emitting laser diode intermediates separated from the wafer in FIG. 4A prior to removing material from a side of the base to achieve a target distance;

FIG. 4C is a top view of the bar in FIG. 4B after removing material from a side of the base to achieve a target distance;

FIG. 4D is a top view of the bar in FIG. 4C after depositing a dielectric passivation material on the side and depositing metal solder material over the dielectric passivation material;

FIG. 5A is an enlarged top view of an edge-emitting laser diode after being separated from the bar shown in FIG. 4D;

FIG. 5B is a cross-sectional, elevation view along the length of the edge-emitting laser diode shown in FIG. 5A;

FIG. 6 is a cross-sectional, elevation view showing the edge-emitting laser diode in FIG. 5B mounted to a slider without a submount;

FIG. 7A is an exploded, perspective view of an example of a hard-disk drive that may include a read/write head having an edge-emitting laser diode according to the present disclosure;

FIG. 7B is a perspective view of the hard-disk drive shown in FIG. 7A in its assembled configuration and showing interior components in broken lines; and

FIG. 8 is a block diagram of a data center system including a plurality of data storage devices according to the present disclosure.

### DETAILED DESCRIPTION

Heat-assisted magnetic recording (HAMR) read/write heads may employ a laser diode to deliver optical energy to a waveguide in a slider for coupling to a near-field transducer. In some approaches, the laser diode may be assembled on a submount and then attached to the slider, which can be referred to as laser-on-slider (LOS).

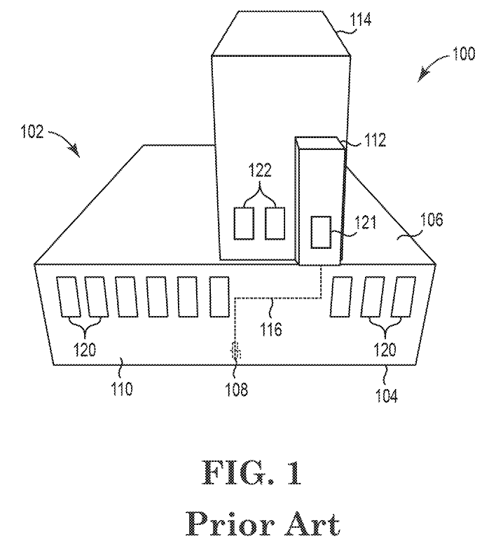

FIG. 1 is a perspective view of a non-limiting example of an apparatus 100 such as an LOS assembly or slider assembly. The apparatus 100 includes a slider 102 having a media-facing surface 104 and a top surface 106. The media-facing surface 104 faces a magnetic media surface (e.g., disk surface, not shown) during operation. A read/write head region 108 is located at the media-facing surface 104 near a trailing edge 110 of the slider body. The read/write head region 108 includes one or more read transducers and write transducers, as well as an optical component (e.g., a near-field transducer) that directs a small beam of energy onto the media surface. The energy is provided by an edge-emitting laser diode 112 attached to a submount 114, both of which are attached to the top surface 106 of the slider 102.

The edge-emitting laser diode 112 directs light to an optical interface (not shown) of the slider 102, where it is coupled to a waveguide 116 that directs light to the read/write head region 108. The edge-emitting laser diode 112 may be coupled to the waveguide 116 via a facet, grating, lens or other coupling structure known in the art. The slider 102 is an integrated optics device that is formed together with the waveguide 116 and read/write head region 108.

The field of integrated optics relates to the construction of optics devices on substrates, sometimes in combination with electronic components, to produce functional systems or subsystems. The processes used are similar to those used in semiconductor fabrication, e.g., layer deposition, photomasking, etching, etc. For example, a component such as the waveguide 116 may be formed as a layer of materials with appropriate relative refractive indices so that light propagates through the waveguide in a manner similar to an optic fiber.

The edge-emitting laser diode 112 and submount 114 may also be formed using integrated optics and/or integrated circuit manufacturing processes. However, in this example, the edge-emitting laser diode 112 and submount 114 are not formed together with the slider 102 in the same layer deposition process. The edge-emitting laser diode 112 and submount 114 are formed separately and later attached together (e.g., using pick and place then solder reflow bonding) with the slider 102 to form the apparatus 100. The slider 102, edge-emitting laser diode 112 and submount 114 have electrical connecting pads 120, 121, and 122 that attach to other structures that are part of what is referred to as a head-gimbal assembly (not shown).

A submount such as submount 114 may provide a carrier for handling and attaching the edge-emitting laser diode 112, and may provide mechanical support for the edge-emitting laser diode 112 during processing and assembly. In some embodiments, the submount may enable thinning of a laser diode substrate, may provide a reference surface for fixturing and alignment, and may shield the edge-emitting laser diode 112 from mechanical and particulate damage during bar-level or device-level operations, such as dicing and lapping. The submount may also provide a platform for electrical routing and thermal conduction between the laser diode 112 and the slider 102. However, use of the submount may add component cost, may add assembly steps, and may add stack-up tolerances associated with attaching the edge-emitting laser diode 112 to the submount and attaching the submount to the slider 102. In the absence of a submount, the edge-emitting laser diode 112 may be exposed to bar-level and device-level operations while supported primarily by the edge-emitting laser diode substrate. In some embodiments, this can increase technical challenges associated with achieving and maintaining a target geometry for optical coupling, including controlling a distance from a front facet of the edge-emitting laser diode 112 to an edge of the edge-emitting laser diode substrate (“z-gap”) that may be targeted at less than about 3 micrometers. In some embodiments, the absence of a submount can also increase susceptibility of a facet and adjacent structures to chipping, contamination, or other damage during singulation and dimensional-control operations, and may increase sensitivity of optical alignment to handling variation. Transfer-print-based approaches may also introduce mechanical stress (e.g., bowing) that can impact manufacturability and reliability.

According to the present disclosure, an edge-emitting laser diode manufacturing process for, e.g., laser-on-slider (LOS) applications, may use etched-facet edge-emitting laser diodes and may protect the etched facets by wafer-level deposition of a dielectric encapsulation material. The dielectric encapsulation material may enable subsequent bar-level processing without relying on a submount, if desired, including singulation and material removal to form and control a distance from the second etched facet to an edge of the base (the "z-gap"), for example via bar-level lapping using electronic lapping guide (ELG) pads formed on the dielectric encapsulation material, and/or via plasma dicing or related bar processes. After achieving the target z-gap, the edge-emitting laser diode may be passivated with a dielectric passivation material and prepared with a metal solder material for attachment. The resulting singulated edge-emitting laser diode may then be mounted to a slider, e.g., using a high-volume laser attach process, with the second etched facet optically coupled to a waveguide in the slider for delivery of light to a near-field transducer.

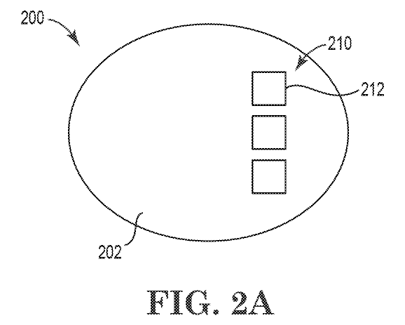

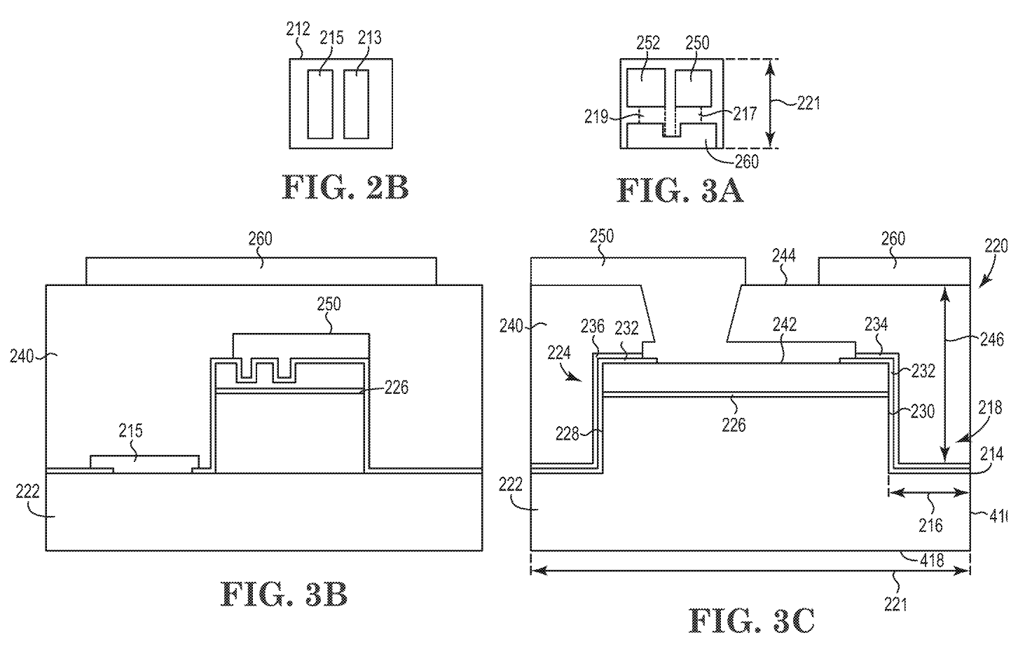

Methods of making edge-emitting laser diodes according to the present disclosure, and the resulting edge-emitting laser diode, will be described in more detail below with reference to FIGS. 2A-6.

Wafer-level fabrication of edge-emitting laser diodes, e.g., for laser-on-slider (LOS) applications, begins with semiconductor processing performed at the wafer scale, enabling high-volume, parallel manufacture of laser diode units prior to assembly onto sliders. Referring now to FIG. 2A, a top view of a non-limiting example of a wafer (200) is shown, depicting a plurality of edge-emitting laser diode intermediates (210) during manufacture. The wafer (200) includes a substrate (202) on which the plurality of edge-emitting laser diode intermediates (210) are arranged in rows and columns. Each edge-emitting laser diode intermediate (212) is fabricated using semiconductor processing techniques, including layer deposition, photolithography, and etching, to define the structures of the edge-emitting laser diode intermediate (212) on the substrate (202). FIG. 2A and FIG. 2B depict the wafer (200) after etching but prior to encapsulation with a dielectric encapsulation material at the wafer level; the etched facets and internal layer structure of the edge-emitting laser diode intermediate (212) are shown in FIGS. 3B and 3C.

FIG. 2B is an enlarged top view of the edge-emitting laser diode intermediate (212) shown in FIG. 2A, depicted prior to encapsulation. As shown in FIG. 2B, a p-metal base layer (213) and an n-metal base layer (215) are visible on the edge-emitting laser diode intermediate (212) prior to encapsulation. The p-metal base layer (213) may be built up, for example by metal deposition, to form the p-metal electrical contact (250) such that the p-metal base layer (213) is electrically and physically connected to the p-metal electrical contact (250). A portion (217) of the p-metal base layer (213) may be encapsulated by the dielectric encapsulation material (240) in a subsequent wafer-level processing step, as indicated by the dashed lines in FIG. 3A. The portion of the p-metal electrical contact (250) that is not encapsulated by the dielectric encapsulation material (240) remains exposed for subsequent electrical connection to a corresponding electrical trace (not shown), such as in a head-gimbal assembly (not shown). Similarly, the n-metal base layer (215) may be built up, for example by metal deposition, to form the n-metal electrical contact (252) such that the n-metal base layer (215) is electrically and physically connected to the n-metal electrical contact (252). A portion (219) of the n-metal base layer (215) may be encapsulated by the dielectric encapsulation material (240) in a subsequent wafer-level processing step, as indicated by the dashed lines in FIG. 3A. The portion of the n-metal electrical contact (252) that is not encapsulated by the dielectric encapsulation material (240) remains exposed for subsequent electrical connection to a corresponding electrical trace (not shown).

Referring now to FIGS. 3A–3C, the edge-emitting laser diode intermediate (212) is shown after encapsulation with the dielectric encapsulation material (240) at the wafer level. FIG. 3A is an enlarged top view of the edge-emitting laser diode intermediate (212) after encapsulation. FIG. 3B is a cross-sectional elevation view along the width of the edge-emitting laser diode intermediate (212), and FIG. 3C is a cross-sectional elevation view along the length of the edge-emitting laser diode intermediate (212). As shown in FIGS. 3B and 3C, each edge-emitting laser diode intermediate (212) includes a body (220) having a base (222) and a ridge waveguide (224) disposed adjacent to the base (222). The ridge waveguide (224) includes an active region (226) configured to generate light. A first etched facet (228) and a second etched facet (230) are formed in the edge-emitting laser diode intermediate (212) such that the active region (226) is disposed between the first etched facet (228) and the second etched facet (230). The first etched facet (228) and the second etched facet (230) may be formed by etching, such as dry etching or reactive ion etching, at the wafer level prior to singulation. The ridge waveguide (224) may be configured to confine light generated in the active region (226) and to direct light toward the second etched facet (230). As shown in FIG. 3C, a first dielectric layer (232) may be deposited on the first etched facet (228) and the second etched facet (230) and may function as a passivation layer and provide optical mirror properties at each of the first etched facet (228) and the second etched facet (230). A second dielectric layer (234) may be deposited on the second etched facet (230) and may provide optical mirror properties at the second etched facet (230). A metal layer (236) may be deposited on the first etched facet (228) and may provide optical mirror properties at the first etched facet (228). The dielectric encapsulation material (240) encapsulates at least the first etched facet (228) and the second etched facet (230), including the first dielectric layer (232), the second dielectric layer (234), and the metal layer (236), as shown in FIGS. 3A–3C. The p-metal electrical contact (250) and the n-metal electrical contact (252) extend from the body (220) through the dielectric encapsulation material (240) and remain exposed for subsequent electrical connection to a corresponding electrical trace (not shown).

As shown in FIGS. 3B and 3C, the dielectric encapsulation material (240) overlies at least a portion of a major surface (242) of the ridge waveguide (224) that extends between the first etched facet (228) and the second etched facet (230). The dielectric encapsulation material (240) has a thickness (246) extending from the ledge (218) along the second etched facet (230) to a major surface (244) of the dielectric encapsulation material (240). The type and thickness (246) of the dielectric encapsulation material (240) may be selected to provide protection to the first etched facet (228) and the second etched facet (230) during subsequent bar-level processing, including material removal operations used to reduce the distance (216) from the second etched facet (230) to the edge of the base (214), e.g., to less than 3 micrometers, for example from 0.1 micrometers to 2 micrometers, which also corresponds to a reduction in the length (221) of the base (222). In some embodiments, the thickness (246) may be at least one micrometer, for example from 1 to 20 micrometers, or even from 1 to 10 micrometers. In some embodiments, the dielectric encapsulation material (240) may include aluminum oxide (Al₂O₃) (270), silicon dioxide (SiO₂) (272), or a combination thereof.

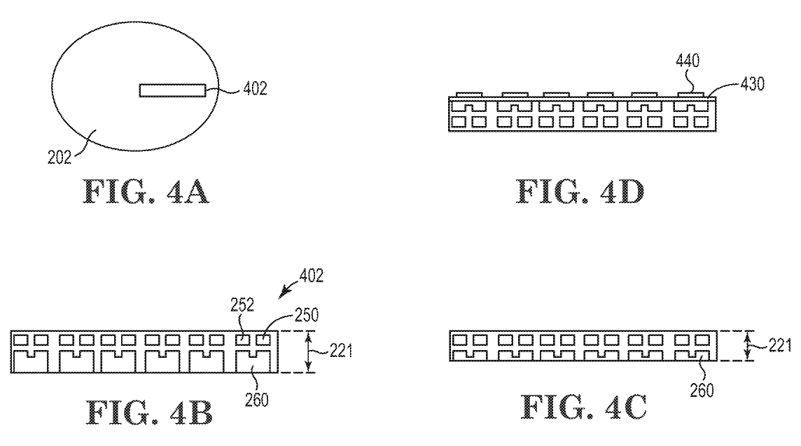

Optionally, in some embodiments, at least one electronic lapping guide (260) may be disposed on the major surface (244) of the dielectric encapsulation material (240), as shown in FIG. 3A. The electronic lapping guide (260) may be used to monitor and control material removal during bar-level lapping operations to achieve the target distance (216), as described in connection with FIGS. 4B and 4C below.

Referring now to FIG. 4A, a top view of a row (400) of edge-emitting laser diode intermediates (210) on the wafer (200) is shown prior to separation into a bar. In some embodiments, the wafer (200) may include a plurality of rows (400), each row (400) including a plurality of edge-emitting laser diode intermediates (212) arranged along a common axis. Each row (400) may be separated from the wafer (200) to form a bar (402), as described in connection with FIG. 4B below. The wafer (200) may be separated into a plurality of bars (402) using any suitable technique, including scribing, blade dicing, laser dicing, or combinations thereof.

Referring now to FIG. 4B, a top view of a bar (402) is shown after separation from the wafer (200) and prior to material removal from the base (222). The bar (402) includes a single row of a portion of the plurality of edge-emitting laser diode intermediates (212). As shown in FIG. 4B, the length (221) of the base (222), and the distance (216) from the second etched facet (230) to the edge of the base (214), may be greater than the target length (221) and distance (216) prior to material removal. In some embodiments, the target distance (216) may be less than 3 micrometers. The dielectric encapsulation material (240) and the at least one electronic lapping guide (260) disposed on the major surface (244) of the dielectric encapsulation material (240) are visible in the top view of FIG. 4B, and may be used to monitor and control material removal during subsequent lapping operations to achieve the target distance (216).

Referring now to FIG. 4C, a top view of the bar (402) is shown after removing material from a side (416) of the base (222) to reduce the distance (216) from the second etched facet (230) to the edge of the base (214) to a target distance of less than 3 micrometers. In some embodiments, removing material from the side (416) of the base (222) may be performed by lapping, and the electronic lapping guide (260) may be used to monitor and control the lapping operation to achieve the target distance (216). In some embodiments, removing material from the side (416) of the base (222) may be performed by plasma etching-assisted cleaving or plasma etching-assisted dicing. The dielectric encapsulation material (240) may protect the first etched facet (228) and the second etched facet (230) during the material removal operation. As shown in FIG. 3C, the side (416) of the base (222) extends from the edge of the base (214) to the major surface (418) of the base (222) following material removal.

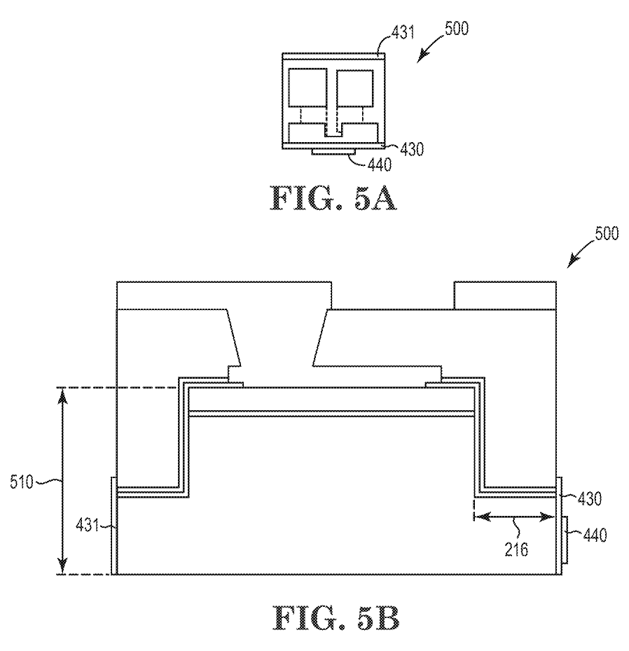

Referring now to FIG. 4D, a top view of the bar (402) is shown after depositing a dielectric passivation material (430) on the side (416) of the base (222) and depositing a metal solder material (440) over the dielectric passivation material (430). The dielectric passivation material (430) may be deposited on the side (416) following material removal to passivate exposed surfaces of the base (222) at the side (416). In some embodiments, the dielectric passivation material (430) may include any suitable dielectric material compatible with a subsequent solder reflow process. The metal solder material (440) may be deposited over the dielectric passivation material (430) to prepare each edge-emitting laser diode intermediate (212) on the bar (402) for subsequent attachment to a slider (600), e.g., using a high-volume laser attach process. In some embodiments, the metal solder material (440) may include any suitable solder alloy compatible with the high-volume laser attach process. Following deposition of the dielectric passivation material (430) and the metal solder material (440), each bar (402) may be separated into a plurality of edge-emitting laser diodes (500) by cleaving or dicing, as described in connection with FIG. 5A below.

Referring now to FIG. 5A, an enlarged top view of a singulated edge-emitting laser diode (500) is shown after separation from the bar (402). The edge-emitting laser diode (500) retains the body (220), base (222), ridge waveguide (224), active region (226), first etched facet (228), second etched facet (230), and dielectric encapsulation material (240) as described in connection with FIGS. 3A–3C. As shown in FIG. 5A, the dielectric passivation material (430) and the metal solder material (440) are disposed on the side (416) of the base (222). In some embodiments, an additional dielectric passivation material (431) may optionally be disposed on the base (222), if desired. The p-metal electrical contact (250) and the n-metal electrical contact (252) remain exposed on the edge-emitting laser diode (500) for subsequent electrical connection to a corresponding electrical trace (not shown).

Referring now to FIG. 5B, a cross-sectional elevation view along the length of the edge-emitting laser diode (500) is shown. As shown in FIG. 5B, the dielectric passivation material (430) and the metal solder material (440) are disposed on the side (416) of the base (222), with the distance (216) from the second etched facet (230) to the edge of the base (214) at the target distance, e.g., of less than 3 micrometers. Also, a thickness (510) extends from the major surface (418) of the base (222) to a major surface (242) of the ridge waveguide (224) that is opposite the major surface (418) of the base (222). In some embodiments, the thickness (510) may be from 100 micrometers to 1000 micrometers, or even from 150 micrometers to 400 micrometers. In some embodiments, the etched-facet process used to form the first etched facet (228) and the second etched facet (230) may allow the thickness (510) to be greater than that of a laser diode formed using a cleaved-facet process, which may provide greater structural robustness during bar-level processing and device-level handling. In some embodiments, the greater thickness (510) may reduce susceptibility to mechanical stress during processing operations, such as transfer printing, such that a separate submount may be avoided, if desired.

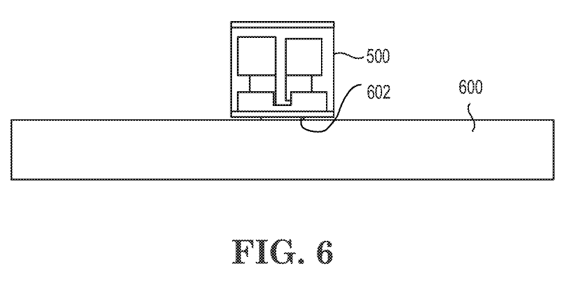

Referring now to FIG. 6, a cross-sectional elevation view is shown of the edge-emitting laser diode (500) mounted to a slider (600) without a submount. The slider (600) is an example of a component of an apparatus that the edge-emitting laser diode (500) can be mounted to.

The slider (600) includes an external mounting surface (602) on which the edge-emitting laser diode (500) is mounted such that the metal solder material (440) on the side (416) of the base (222) is in contact with the external mounting surface (602). The slider (600) further includes a waveguide (like waveguide 116 in FIG. 1) disposed in the slider (600) and a near-field transducer (like the near-field transducer in read/write head region 108 in FIG. 1) disposed in the slider (600) and optically coupled to the waveguide. The edge-emitting laser diode (500) is mounted to the external mounting surface (602) such that the second etched facet (230) is optically coupled to the waveguide to communicate light generated in the active region (226) to the waveguide for delivery to the near-field transducer. In some embodiments, the slider (600) and the edge-emitting laser diode (500) mounted thereon may form a heat-assisted magnetic recording read/write head. The edge-emitting laser diode (500) may be mounted to the external mounting surface (602) of the slider (600) using a high-volume laser attach process, such as solder reflow, without requiring a submount between the edge-emitting laser diode (500) and the slider (600), if desired.

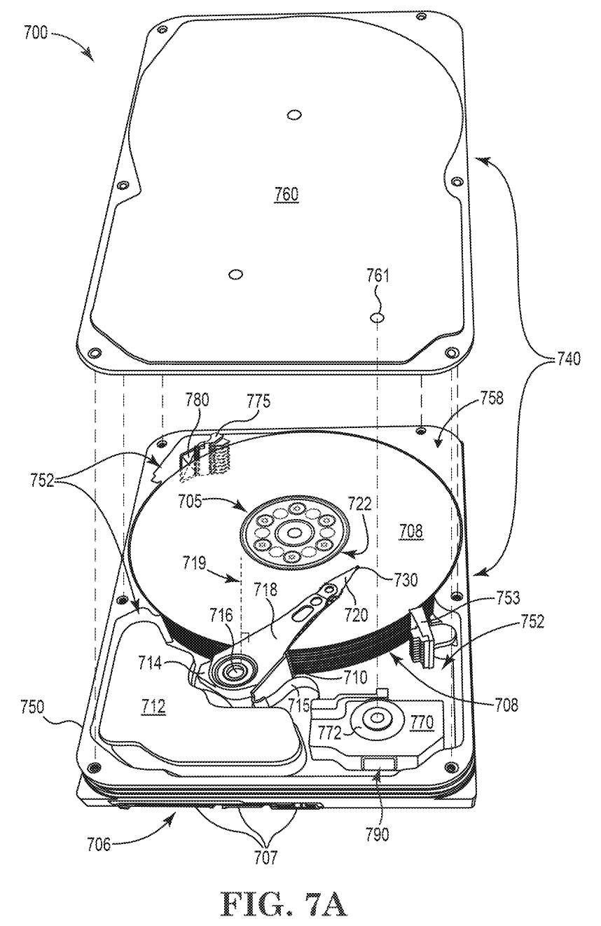

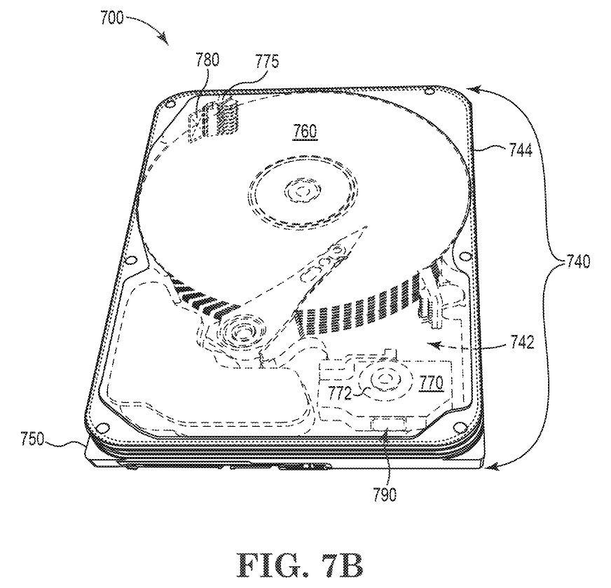

An apparatus that includes an edge-emitting laser diode according to the present disclosure can be used in a data storage device such as a hard disk drive. A non-limiting example of a hard disk drive that can use an edge-emitting laser diode according to the present disclosure is illustrated in FIGS. 7A and 7B.

Data storage device 700 is illustrated as a hard-disk drive (HDD) that includes an outer enclosure or housing 740 configured to contain multiple hard-disk drive components, including electronic components. Housing 740 includes a base 750 and a cover 760 mounted to the base 750. Base 750 includes a recess or cavity 752 configured to accommodate components of data storage device 700. Base 750 can also be referred to as a motor base assembly (MBA). Data storage device 700 further includes a printed circuit board assembly (PCBA) 706. PCBA 706 of this configuration is coupled to base 750 and includes a plurality of input/output connectors 707 that are each configured to provide an interface between one or more components of data storage device 700 and one or more host devices (e.g., a computer, a server, a consumer electronic device, or the like).

Base 750 and cover 760 may be formed from any suitable material, such as metal (e.g., aluminum), plastic, or other suitable materials or combinations thereof. In some embodiments, base 750 includes multiple components, such as an outer frame and a bottom cover, that are coupled together (e.g., by screws, welding, or the like).

Cover 760 is configured to couple to base 750 to enclose components of data storage device 700, as shown in FIG. 7B. As shown, cover 760 is aligned with and coupled to a surface of base 750, such as a surface 758 shown in FIG. 7A, to define an interior volume 742 of data storage device 700, which includes an interior gas space. A load/unload ramp 753 is also positioned in interior volume 742. Components other than those illustrated or specifically identified in FIGS. 7A and 7B and described herein are contemplated as being positioned within the interior volume 742, such as a preamp and/or assembly hardware, for example. Cover 760 can be coupled to the base 750 using any suitable technique, such as using one or more screws, connection fingers, locking/clipping structures, adhesives, rivets, other mechanical fasteners, welding (e.g., ultrasonic welding) or combinations thereof. In some embodiments, data storage device 700 can further include one or more seals disposed between base 750 and top cover 760 and configured to seal the interior volume 742 of data storage device 700. In some embodiments, seal 744 can be a weld formed between base 750 and cover 760, or seal 744 can be a form-in-place gasket (FIPG).

A gas or gas mixture may be added to interior volume 742 of data storage device 700. Helium, for example, may be included in interior volume 742 to reduce mechanical vibrations, particularly of head gimbal assemblies (HGAs) of data storage device 700. Helium may also be included within data storage device 700 to enable lower head-media spacing (HMS) between a reader and/or writer of a magnetic recording head and a magnetic disk, and thus a higher areal density capability (ADC) of data storage device 700. The interior gas space of the interior volume 742 may benefit from a small amount of oxygen. In some embodiments, interior gas space can have an oxygen concentration in the range from 0.1 to less than 20 mole percent, from 0.1 to 15 mole percent, or even from 3 to 15 mole percent based on the total gas in the interior gas space, with the balance being helium.

In some embodiments, data storage device 700 can be a sealed (hermetically sealed) data storage device, which can be defined by, e.g., the amount of gas (e.g., helium) that leaks from the data storage device after it has been sealed (e.g., a welded HDD). In some embodiments, a hermetically sealed data storage device having its interior gas space filled with helium gas has a nominal helium leak rate of less than 10% by volume in five years. In some embodiments, in terms of (atm cc / second), a hermetically sealed data storage device having its interior gas space filled with helium gas has a nominal helium leak rate of 10 x10^-8 atm (atmosphere) cc (cubic centimeter)/ second or less at 25°C; 7 x10^-8 atm cc / second or less, 5x10^-8 atm cc / second or less; or even 4x10^-8 atm cc / second or less at 25°C. As mentioned above, a form-in-place gasket can be used to help seal a data storage device.

Data storage device 700 includes an actuator 710, which includes a head stack assembly (HSA) 714 and voice coil motor 712. Head-stack assembly 714 is rotatably mounted to the base 750, and includes radially-extending arms 718 that are rotatable about an axis 719 that is perpendicular to the floor of base 750 as shown in FIG. 7A. Data storage device 700 includes one or more magnetic disks configured to store bits of data. HSA 714 further includes a plurality of head-gimbal assemblies (HGAs). Each HGA 720 includes a read/write head 730 for reading data from and writing data to a surface of a magnetic disk 708. HSA 714 can include one or more subcomponents. Non-limiting examples of such subcomponents include a hookup 715 (a flex cable and a flex clamp) and/or adhesives. Other components of a read/write head 730 can be included, such as heaters, heat sinks, and piezoelectric actuators, for example.

Voice coil motor 712 produces a magnetic field that exerts a force on HSA 714, causing radially-extending arms to rotate about a shaft 716 in either rotational direction. Each radially-extending arm 718 is mechanically and rotatably coupled to shaft 716 such that as HSA 714 rotates, it causes each radially-extending arm 718, and thus magnetic recording heads, to move relative to magnetic disks 708. Voice coil motor 712 includes magnets and a voice coil.

Data storage device 700 further includes a motor assembly 705 configured to rotatably support magnetic disks and circumferentially rotate magnetic disks about an axis of rotation during operation. Magnetic disks are mounted on motor assembly 705 such that an annular volume of each magnetic disk 708 encircles a portion of motor assembly 705. Further, magnetic disks are separated from each other in a stacked manner using spacers (not shown). Motor assembly 705 has an outside diameter 722 and may rotate magnetic disks during an operation of data storage device 700 such that each magnetic disk 708 moves relative to a respective read/write head 730 to enable the read/write heads to read data from and/or write data to the magnetic disk 708.

Data storage device 700 includes a diverter 775 that is proximal to magnetic disks 708. Diverter 775 is configured to divert helium and/or other interior gas mixture(s) to reduce windage on each radially-extending arm 718, which can reduce undesired vibrations that may cause a read/write head 730 to move off track and/or contact a magnetic disk 708.

The data storage device 700 includes components having an adsorbent composition in the form of an article that permits the components to be positioned and/or mounted in the interior volume 742 of data storage device 700 so that the adsorbent composition can adsorb moisture and/or organic vapors from the interior gas. In some embodiments, a component can also include filtering capability to remove organic particulate material. As shown in FIGS. 7A and 7B, non-limiting examples of such components include an environmental control module 770, a recirculation filter 780, and a label filter 790 for such a purpose. As shown, environmental control module 770 includes an inlet diffuser seal 772 that helps its contents (e.g., environmental control module tablet (not shown)) dry during manufacturing. The environmental control module tablet can become exposed to the interior volume 742 of data storage device 700 by breaking the seal located at the bottom center of inlet diffuser seal 772 to create an opening (not shown) so that gas exchange can occur between the inside of environmental control module 770 and the interior volume 742.

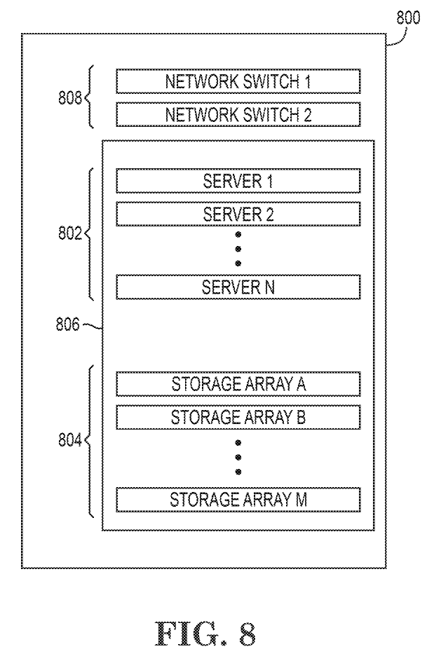

FIG. 8 illustrates a non-limiting example of a computing system 800 that includes a plurality of data storage devices (e.g., data storage device 700) that include an edge-emitting laser diode according to the present disclosure. In FIG. 8, a diagram shows a computing system 800 that can have a computing enclosure used in network storage services. As shown, the computing enclosure includes a plurality of servers 802 coupled to a plurality of drive arrays 804 via a rack-level network fabric 806. Each server 802 can include at least one CPU coupled to random access memory (RAM) and an input/output (IO) subsystem. Each server 802 may have one or more dedicated power supplies (not shown) or the enclosure may provide power through a power bus (not shown). Each server 802 may also have an IO interface for connecting to the rack-level network fabric 806. The rack-level network fabric 806 may use other rack-level networking technology such as switches 808.

The drive arrays 804 may each include a separate sub-enclosure with IO buses, power supplies, storage controllers, etc. The drive arrays 804 include a plurality of individual data storage devices (e.g., HDD) densely packed into the sub-enclosure. An example of a data center that includes a computing system having a plurality of data storage devices is also described in U.S. Pat. No. 11,567,834 (Bent et al.).

What is claimed is:

1. An edge-emitting laser diode comprising a body, wherein the body comprises:
a base; and
a ridge waveguide disposed adjacent to the base, wherein the ridge waveguide
comprises an active region;
a first etched facet;
a second etched facet, wherein the active region is disposed between the
first etched facet and the second etched facet, wherein the ridge waveguide is configured to confine light generated in the active region and direct light toward the second etched facet;
a p-metal electrical contact; and
an n-metal electrical contact, wherein at least the first etched facet and the
second etched facet are encapsulated in a dielectric encapsulation material such that the p-metal electrical contact and the n-metal electrical contact extend from the body through the dielectric encapsulation material so that each of the p-metal electrical contact and the n-metal electrical contact are exposed for electrical connection, and wherein the edge-emitting laser diode is configured to be mounted to an external surface of a component of an apparatus to communicate light from the second etched facet of the edge-emitting laser diode to a waveguide in the apparatus.

2. The edge-emitting laser diode of claim 1, wherein a distance extends from the second etched facet to an edge of the base to define a ledge, wherein the distance is less than 3 micrometers.

3. The edge-emitting laser diode of claim 2, wherein the dielectric encapsulation material overlies at least a portion of a major surface of the ridge waveguide that extends between the first etched facet and the second etched facet, wherein the dielectric encapsulation material has a thickness extending from the ledge along the second etched facet to a major surface of the dielectric encapsulation material, and wherein the thickness is at least one micrometer.

4. The edge-emitting laser diode of claim 3, further comprising at least one electronic lapping guide disposed on the major surface of the dielectric encapsulation material.

5. The edge-emitting laser diode of claim 2, wherein the base has a side that extends from the edge to a major surface of the base, wherein a layer of dielectric passivation material is present on the side.

6. The edge-emitting laser diode of claim 5, further comprising a metal solder material disposed on the layer of dielectric passivation material.

7. The edge-emitting laser diode of claim 1, wherein the dielectric encapsulation material comprises at least one of aluminum oxide (Al₂O₃) or silicon dioxide (SiO₂).

8. The edge-emitting laser diode of claim 1, wherein the laser diode has a thickness extending from a major surface of the base to a major surface of the ridge waveguide that is opposite the major surface of the base, wherein the thickness is from 100 micrometers to 1000 micrometers.

9. A wafer comprising:
a substrate; and
a plurality of edge-emitting laser diode intermediates, wherein each edge-emitting laser diode intermediate comprises a body, wherein the body comprises:
a base; and
a ridge waveguide disposed adjacent to the base, wherein the ridge waveguide
comprises an active region;
a first etched facet;
a second etched facet, wherein the active region is disposed between the
first etched facet and the second etched facet, wherein the ridge waveguide is configured to confine light generated in the active region and direct light toward the second etched facet;
a p-metal electrical contact; and
an n-metal electrical contact, wherein at least the first etched facet and the
second etched facet are encapsulated in a dielectric encapsulation material such that the p-metal electrical contact and the n-metal electrical contact extend from the body through the dielectric encapsulation material so that each of the p-metal electrical contact and the n-metal electrical contact are exposed for electrical connection, and wherein the edge-emitting laser diode is configured to be mounted to an external surface of a component of an apparatus to communicate light from the second etched facet of the edge-emitting laser diode to a waveguide in the apparatus.

10. A bar comprising:
a substrate; and
a single row of a plurality of edge-emitting laser diode intermediates, wherein each edge-emitting laser diode intermediate comprises a body, wherein the body comprises:
a base; and
a ridge waveguide disposed adjacent to the base, wherein the ridge waveguide
comprises an active region;
a first etched facet;
a second etched facet, wherein the active region is disposed between the
first etched facet and the second etched facet, wherein the ridge waveguide is configured to confine light generated in the active region and direct light toward the second etched facet;
a p-metal electrical contact; and
an n-metal electrical contact, wherein at least the first etched facet and the
second etched facet are encapsulated in a dielectric encapsulation material such that the p-metal electrical contact and the n-metal electrical contact extend from the body through the dielectric encapsulation material so that each of the p-metal electrical contact and the n-metal electrical contact are exposed for electrical connection, and wherein the edge-emitting laser diode is configured to be mounted to an external surface of a component of an apparatus to communicate light from the second etched facet of the edge-emitting laser diode to a waveguide in the apparatus.

11. An apparatus comprising:
a slider having an external mounting surface; and
an edge-emitting laser diode of claim 1 mounted on the external mounting surface.

12. The apparatus of claim 11, wherein the slider further comprises a waveguide disposed in the slider, wherein the second etched facet is optically coupled to the waveguide so that the waveguide receives light from the second etched facet.

13. The apparatus of claim 12, wherein the slider further comprises a near-field transducer disposed in the slider and optically coupled to the waveguide to receive light from the waveguide.

14. The apparatus of claim 13, wherein the apparatus is a heat-assisted magnetic recording read/write head.

15. A data storage device comprising at least one apparatus of claim 11.

16. A computing system comprising a plurality of data storage devices of claim 15.

17. A method comprising:
etching a plurality of edge-emitting laser diode intermediates disposed on a wafer to form a first etched facet and a second etched facet in each of the plurality of edge-emitting laser diode intermediates, wherein an active region is disposed between the
first etched facet and the second etched facet, and wherein each edge-emitting laser diode intermediate comprises a ridge waveguide configured to confine light generated in the active region and direct light toward the second etched facet;
encapsulating at least the first etched facet and the second etched facet in a dielectric encapsulation material.

18. The method of claim 17, further comprising:
forming a plurality of bars from the wafer after the encapsulating, wherein each bar comprises a single row of a portion of the plurality of edge-emitting laser diode intermediates, wherein each edge-emitting laser diode intermediate comprises:
a base; and
a ridge waveguide disposed adjacent to the base, wherein the ridge waveguide
comprises an active region;
the first etched facet; and
the second etched facet, wherein the active region is disposed between the
first etched facet and the second etched facet, wherein the ridge waveguide is configured to confine light generated in the active region and direct light toward the second etched facet; and
removing material from a side of the base to reduce a distance that extends from the second etched facet to an edge of the base, wherein after removing the material the distance is less than 3 micrometers.

19. The method of claim 18, wherein removing material from a side of the base is performed using at least one of lapping, plasma etching-assisted cleaving, or plasma etching-assisted dicing.

20. The method of claim 19, further comprising:
after removing the material, depositing a dielectric passivation material on the side;
depositing metal solder material over the dielectric passivation material;
separating each bar into a plurality of edge-emitting laser diodes;
mounting at least one of the plurality of edge-emitting laser diodes to a slider.
